(19) United States
(12) Patent Application Publication
(10) Pub. No.: US 2025/0175130 A1
(43) Pub. Date: May 29, 2025

(54) AMPLIFYING CIRCUIT

(71) Applicant: Sumitomo Electric Industries, Ltd., Osaka (JP)

(72) Inventor: Shuichi NISHIMURA, Osaka-shi (JP)

(73) Assignee: Sumitomo Electric Industries, Ltd., Osaka (JP)

(21) Appl. No.: 18/956,965

(22) Filed: Nov. 22, 2024

(30) Foreign Application Priority Data
Nov. 24, 2023 (JP) 2023-199228

(51) Int. Cl. H03F 1/56; H03F 3/213

(52) U.S. Cl. CPC H03F 1/565; H03F 3/213; H03F 2200/222; H03F 2200/387

(57) ABSTRACT

An amplifying circuit includes an amplifier that outputs an amplified high frequency signal to an output terminal, a first inductor connected to a line between the amplifier and the output terminal, a resistor component connected to the first inductor, the resistor component including an insulated substrate mounted on or over an upper surface of a base substrate and having a thermal conductivity of 20 W/m·K or more and a bandgap energy of 1.5 eV or more, and a resistance film disposed on an upper surface of the insulated substrate, and a first capacitor connected to the resistor component and a reference potential. An absolute value of an impedance of the first inductor at a center frequency of an operating band of the amplifier is larger than an absolute value of an impedance of the first capacitor at a frequency corresponding to a bandwidth of the operating band.

### CROSS REFERENCE TO RELATED APPLICATIONS

This application claims priority based on Japanese Patent Application No. 2023-199228 filed on Nov. 24, 2023, and the entire contents of the Japanese patent application are incorporated herein by reference.

### TECHNICAL FIELD

The present invention relates to an amplifying circuit.

### BACKGROUND

It is known that a baseband termination circuit (video bypass circuit or envelope frequency termination circuit) or the like is provided on a line between an amplifier and an output terminal of a high-power amplifier circuit for a high frequency signal such as microwave (for example, patent literatures 1 to 4, non-patent literatures 1 and 2). It is known that a resistor provided in the baseband termination circuit is disposed on a substrate mounted on a base of a package (for example, patent literature 1 or 2).
Patent literature 1: Japanese Laid-open Patent Application Publication No. 2022-138983
Patent literature 2: EP Patent Application Publication No. 3273596
Patent literature 3: Japanese National Publication of International Patent Application No. 2006-501678
Patent literature 4: Japanese Laid-open Patent Application Publication No. 2018-101975
Non-patent literature 1: Hussain Ladhani et al. “Analysis of the Baseband Termination of High Power RF Transistors” 2019 IEEE/MTT-S International Microwave Symposium
Non-patent literature 2: Ning Zhu et al. “Compact High-Efficiency High-Power Wideband GaN Amplifier Supporting 395 MHz Instantaneous Bandwidth” 2019 IEEE/MTT-S International Microwave Symposium

### SUMMARY

An amplifying circuit according to an embodiment of the present disclosure includes an amplifier that amplifies a high frequency signal input to an input terminal and outputs the amplified high frequency signal to an output terminal, a first inductor having a first end connected to a line between the amplifier and the output terminal, a resistor component having a first end connected to a second end of the first inductor, the resistor component including an insulated substrate mounted on or over an upper surface of a base substrate and having a thermal conductivity of 20 W/m·K or more and a bandgap energy of 1.5 eV or more, and a resistance film disposed on an upper surface of the insulated substrate, and a first capacitor having a first end connected to a second end of the resistor component and a second end connected to a reference potential. An absolute value of an impedance of the first inductor at a center frequency of an operating band of the amplifier is larger than an absolute value of an impedance of the first capacitor at a frequency corresponding to a bandwidth of the operating band.

### BRIEF DESCRIPTION OF THE DRAWINGS

FIG. 1 is a circuit diagram of an amplifying circuit according to a first embodiment.

FIG. 2 is a circuit diagram of a semiconductor device according to the first embodiment.

FIG. 3 is a plan view of a semiconductor device according to the first embodiment.

FIG. 4 is an A-A cross-sectional view of FIG. 3.

FIG. 5 is a B-B cross-sectional view of FIG. 3.

FIG. 6 is a plan view of a resistor component according to the first embodiment.

FIG. 7 is an A-A cross-sectional view of FIG. 6.

FIG. 8 is another circuit diagram of a semiconductor device according to the first embodiment.

FIG. 9 is a plan view of a semiconductor device according to a first modification of the first embodiment.

FIG. 10 is a plan view of a semiconductor device according to a second modification of the first embodiment.

FIG. 11 is a circuit diagram of a semiconductor device according to a second embodiment.

FIG. 12 is a plan view of a semiconductor device according to the second embodiment.

FIG. 13 is a plan view of a semiconductor device according to a first modification of the second embodiment.

FIG. 14 is a circuit diagram of a semiconductor device according to a third embodiment.

FIG. 15 is a plan view of a semiconductor device according to a third embodiment.

FIG. 16 is a plan view of a semiconductor device according to a fourth embodiment.

### DETAILED DESCRIPTION

The baseband termination circuit is configured to exhibit low impedance to signals in the baseband frequency range in order to terminate the signals in the baseband frequency range that is lower than the frequency of the operating band of the amplifier to a reference potential. The baseband termination circuit is configured to have high impedance with respect to the frequency of the operating band of the amplifier so that signals of the frequency of the operating band of the amplifier is prevented from flowing into the baseband termination circuit as much as possible. Thus, it is considered that most of the high power output signal amplified by the amplifier is not applied to the resistor of the baseband termination circuit. However, some of the signals in the operating band may be applied to the resistor of the baseband termination circuit, and the characteristics of the resistor may change or the resistor may deteriorate.

The present disclosure has been made in view of the above problems, and an object of the present disclosure is to suppress a change in the characteristics of a resistor or deterioration of the resistor.

### Description of Embodiments of Present Disclosure

First, the contents of embodiments of the present disclosure will be listed and explained.

(1) An amplifying circuit according to an embodiment of the present disclosure includes an amplifier that amplifies a high frequency signal input to an input terminal and outputs the amplified high frequency signal to an output terminal, a first inductor having a first end connected to a line between the amplifier and the output terminal, a resistor component having a first end connected to a second end of the first inductor, the resistor component including an insulated substrate mounted on or over an upper surface of a base substrate and having a thermal conductivity of 20 W/m·K or more and a bandgap energy of 1.5 eV or more, and a resistance film disposed on an upper surface of the insulated substrate, and a first capacitor having a first end connected to a second end of the resistor component and a second end connected to a reference potential. An absolute value of an impedance of the first inductor at a center frequency of an operating band of the amplifier is larger than an absolute value of an impedance of the first capacitor at a frequency corresponding to a bandwidth of the operating band. This can suppress a change or deterioration in the characteristics of the resistor component due to a temperature rise of the resistor component used in a baseband termination circuit. Deterioration of the resistor component due to application of a high voltage can be suppressed. It is possible to suppress the characteristics of the baseband termination circuit from deviating from desired characteristics due to the parasitic capacitance.

(2) In the above (1), the absolute value of the impedance of the first inductor at the center frequency of the operating band may be 10Ω or more, and the absolute value of the impedance of the first capacitor at the frequency corresponding to the bandwidth of the operating band may be 1Ω or less. This allows the first inductor and the first capacitor to function as a baseband termination circuit.

(3) In the above (1) or (2), the first inductor may have an inductance of 100 pH or more, and the first capacitor may have a capacitance of 100 pF or more. This allows the first inductor and the first capacitor to function as a baseband termination circuit.

(4) The amplifying circuit according to any one of the above (1) to (3) may further include a matching circuit disposed in the line and including a second inductor and a second capacitor. The first inductor may have a larger inductance than the second inductor, and the first capacitor may have a larger capacitance than the second capacitor. This allows the first inductor and the first capacitor to function as a baseband termination circuit.

(5) In any one of the above (1) to (4), the center frequency of the operating band may be 0.5 GHz to 10 GHz, and the bandwidth of the operating band may be 100 MHz or more. This allows the amplifying circuit to be used in a base station of mobile communication.

(6) In the above (5), a saturation power for the high frequency signal to be output from the output terminal may be 10 W or more. Thus, even when a large power is applied to the resistor component, a change or deterioration in the characteristics of the resistor component can be suppressed.

(7) In any one of the above (1) to (6), the first inductor may include a line pattern disposed on the upper surface of the insulated substrate. This can suppress the temperature rise of the first inductor.

(8) The amplifying circuit according to any one of the above (1) to (7) may further include a third capacitor connected in parallel with the first capacitor between the line and the reference potential. Thus, the frequency band suppressed by the baseband termination circuit can be widened. The resistor component can suppress resonance caused by the first capacitor and the second capacitor.

(9) In any one of the above (1) to (8), the insulated substrate may be an aluminum nitride substrate, a gallium nitride substrate, or a silicon carbide substrate. Thus, the deterioration of the resistor component can be suppressed.

(10) In any one of the above (1) to (9), the first capacitor may include a dielectric substrate mounted on or over the upper surface of the base substrate, and an electrode disposed on an upper surface of the dielectric substrate and connected to the second end of the resistor component, and the amplifier may include a semiconductor substrate mounted on or over the upper surface of the base substrate, and a transistor disposed on the semiconductor substrate. This allows the amplifying circuit to be miniaturized.

### Details of Embodiments of Present Disclosure

Specific examples of an amplifying circuit according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

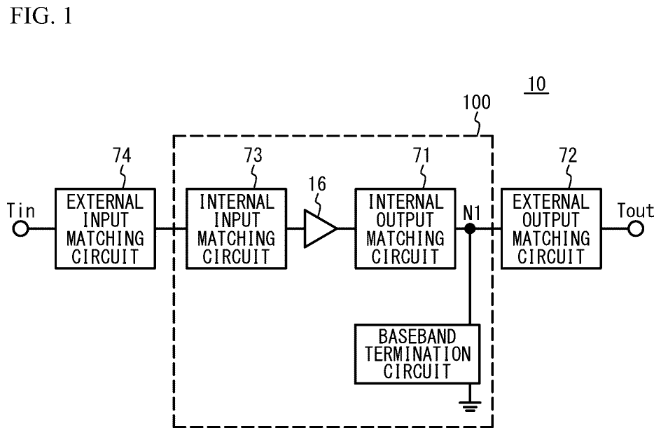

As an amplifying circuit, a high-power high-frequency amplifier circuit used in a base station of mobile communication will be described as an example. FIG. 1 is a circuit diagram of an amplifying circuit according to a first embodiment. As illustrated in FIG. 1, an amplifying circuit 10 includes a semiconductor device 100, an external output matching circuit 72, and an external input matching circuit 74. Semiconductor device 100 includes an amplifier 16, an internal output matching circuit 71, an internal input matching circuit 73, and a baseband termination circuit 70 (also referred to as a video bypass circuit or an envelope frequency termination circuit). An input terminal Tin is connected to amplifier 16 via external input matching circuit 74 and internal input matching circuit 73. External input matching circuit 74 and internal input matching circuit 73 match a load connected to input terminal Tin with an input impedance of amplifier 16.

Amplifier 16 is connected to an output terminal Tout via internal output matching circuit 71 and external output matching circuit 72. Internal output matching circuit 71 and external output matching circuit 72 match a load connected to output terminal Tout with an output impedance of amplifier 16. A high frequency signal input to input terminal Tin is transmitted to amplifier 16 through external input matching circuit 74 and internal input matching circuit 73. Amplifier 16 amplifies the high frequency signal and outputs the amplified signal to output terminal Tout through internal output matching circuit 71 and external output matching circuit 72.

Amplifying circuit 10 includes a node N1 between internal output matching circuit 71 and external output matching circuit 72. Amplifying circuit 10 includes baseband termination circuit 70 having a first end electrically connected to node N1 and a second end electrically connected to a reference potential, such as ground. Baseband termination circuit 70 is a circuit for improving a video bandwidth (VBW). The video bandwidth is used as an indicator of a distortion bandwidth. When VBW is small, measurement of the third order intermodulation distortion (IMD3) of a two-tone signal corresponding to the bandwidth of the amplifier (e.g., 400 MHZ) results in a difference in signal strength between the IMD3 component on the low frequency side and the IMD3 component on the high frequency side. When asymmetry occurs in the IMD3 in this way, distortion compensation using digital predistortion (DPD) cannot provide sufficient distortion characteristics because the amount of distortion improvement is reduced (see, for example, Non-patent literature 1). A cause of this asymmetry of the IMD3 is known to be a second-order intermodulation distortion IMD2 component generated in the difference frequency component of the two-tone signal. This difference frequency component is a signal component of a low frequency band included in the range of the baseband frequency. For this reason, by installing baseband termination circuit 70, the impedance of the low frequency band at node N1 is reduced, thereby increasing the video bandwidth and suppressing the IMD2 component. This improves the asymmetry of the IMD3 and allows the DPD to provide sufficient distortion compensation.

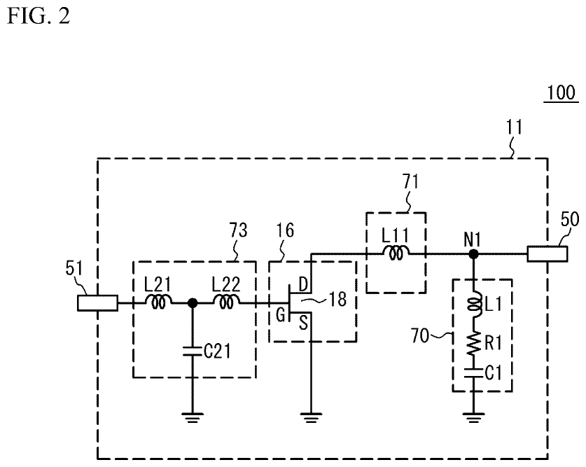

FIG. 2 is a circuit diagram of a semiconductor device according to the first embodiment. As illustrated in FIG. 2, semiconductor device 100 includes a package 11. Amplifier 16, internal output matching circuit 71, internal input matching circuit 73, and baseband termination circuit 70 are mounted in package 11. An output lead 50 and an input lead 51 connect the circuit in package 11 to the outside.

Amplifier 16 includes a transistor 18. Transistor 18 is, for example, a field effect transistor (FET) such as a gallium nitride high electron mobility transistor (GaN HEMT) or a laterally diffused metal oxide semiconductor (LDMOS). A source S of transistor 18 is grounded. A gate G of transistor 18 is electrically connected to input lead 51 via internal input matching circuit 73. A drain D of transistor 18 is electrically connected to output lead 50 via internal output matching circuit 71.

Internal output matching circuit 71 includes an inductor L11. Internal output matching circuit 71 may be a low-pass circuit including two inductors connected in series and a capacitor shunt-connected to a node between the two inductors. Internal output matching circuit 71 may be a high-pass circuit including an inductor connected in series, a shunt-connected inductor, and a direct current cut capacitor connected between the inductor and the ground. The number of inductors and the number of capacitors in internal output matching circuit 71 can be set as appropriate.

Internal input matching circuit 73 is an L-C-L T-type low-pass circuit, and includes inductors L21 and L22 and a capacitor C21. Internal input matching circuit 73 may be only one inductor connected in series. Internal input matching circuit 73 may be a low-pass circuit in which two of L-C-L T-type low-pass circuits are connected in series. Internal input matching circuit 73 may be a circuit in which an inductor and a capacitor connected in series are shunt-connected behind the L-C-L T-type low-pass circuit. The number of inductors and the number of capacitors in internal input matching circuit 73 can be set as appropriate.

Baseband termination circuit 70 includes an inductor L1, a resistor R1, and a capacitor C1. Inductor L1 (first inductor) has a first end electrically connected to node N1 of a line between amplifier 16 and output lead 50. A first end of resistor R1 is electrically connected to a second end of inductor L1. A first end of capacitor C1 (first capacitor) is electrically connected to a second end of resistor R1, and a second end of capacitor C1 is electrically connected to a reference potential.

Inductor L1 has a function of suppressing a high frequency signal of the operating band amplified by amplifier 16 (for example, 0.5 GHz to 10 GHZ) from passing through capacitor C1 to the ground. Thus, inductor L1 has an inductance such that it has a high impedance in the frequency band of the operating band. Inductor L1 has an inductance of, for example, 1 nH or more. Capacitor C1 has a low impedance at a frequency (for example, more than 0 MHz and 400 MHz or less) corresponding to the bandwidth of the high frequency signal amplified by amplifier 16. Thus, capacitor C1 has a large capacitance and becomes large in size. Capacitor C1 has a capacitance of, for example, 1 nF or more. Resistor R1 is a damping resistance. For example, when a capacitor (for example, parasitic capacitance) is connected in parallel to capacitor C1 and inductor L1, unnecessary resonance may occur. By providing resistor R1, unnecessary resonance can be suppressed. Resistor R1 has a resistance of, for example, 1Ω to 100Ω.

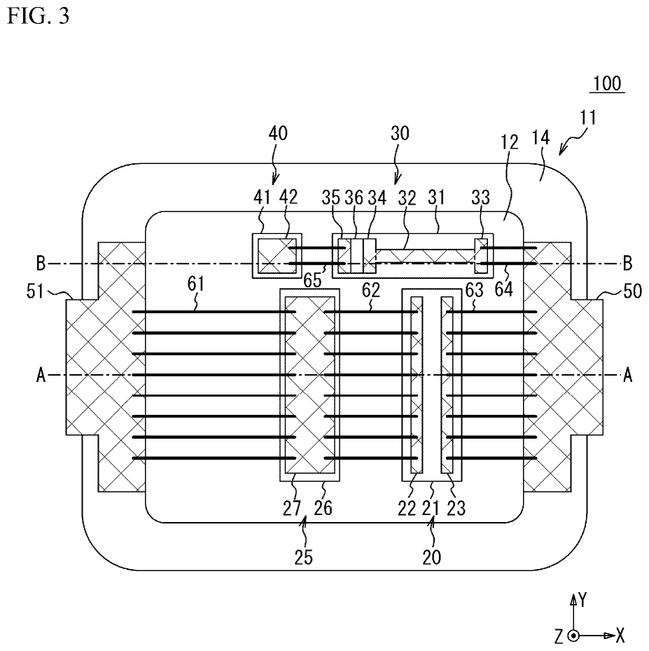

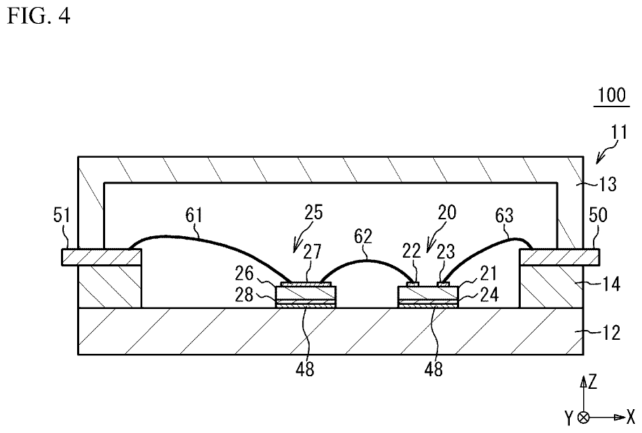

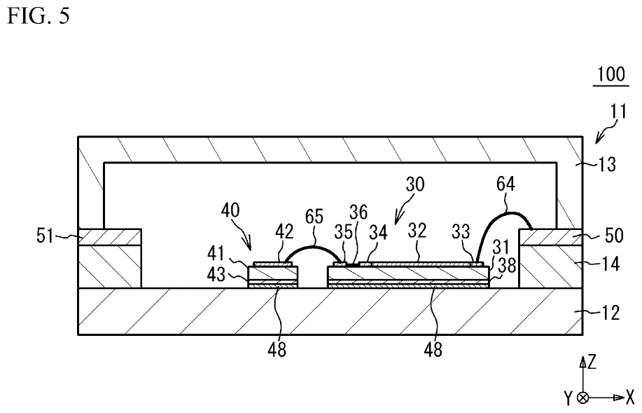

FIG. 3 is a plan view of a semiconductor device according to the first embodiment. FIGS. 4 and 5 are an A-A cross-sectional view and a B-B cross-sectional view of FIG. 3, respectively. A lid 13 is not illustrated in FIG. 3. A normal direction of the upper surface of a base substrate 12 is a Z direction, a direction from input lead 51 to output lead 50 is an X direction, and a direction orthogonal to the X direction and the Z direction is a Y direction.

As illustrated in FIGS. 3 to 5, in semiconductor device 100 of the first embodiment, package 11 includes base substrate 12, a frame body 14, and lid 13. Base substrate 12 is a conductor substrate such as a stacked substrate of copper and molybdenum. A reference potential such as a ground potential is supplied to base substrate 12. Frame body 14 and lid 13 are dielectric layers made of a resin such as flame retardant type 4 (FR-4), or ceramic, for example. A semiconductor chip 20, a resistor component 30, and capacitive components 25 and 40 are mounted on base substrate 12. Capacitive component 25 and semiconductor chip 20 are arranged in the X direction. Frame body 14 is disposed on base substrate 12 so as to surround semiconductor chip 20, resistor component 30, and capacitive components 25 and 40. Frame body 14 is bonded to the upper surface of base substrate 12 with a bonding layer (not illustrated) such as a metal paste or a brazing material. Lid 13 is joined to the upper surface of frame body 14 with an insulating adhesive (not illustrated) such as a resin. Frame body 14 and lid 13 seal semiconductor chip 20 in a space.

A planar shape of frame body 14 is substantially rectangular. Input lead 51 and output lead 50 are substantially T-shaped. Each of input lead 51 and output lead 50 may be formed as one piece by the same metal layer or metal plate. Each of input lead 51 and output lead 50 may be a bar-shaped lead bonded to a metal layer disposed on frame body 14. Input lead 51 and output lead 50 are metal layers or metal plates made of, for example, copper or the like.

Semiconductor chip 20 includes a semiconductor substrate 21, electrodes 22 and 23 disposed on an upper surface of semiconductor substrate 21, and an electrode 24 disposed on a lower surface of semiconductor substrate 21. Electrodes 22, 23 and 24 are a gate electrode, a drain electrode and a source electrode, respectively, and electrodes 22 and 23 are an input pad and an output pad, respectively. Transistor 18 illustrated in FIG. 2 is disposed on semiconductor substrate 21. In FIGS. 3 and 4, transistor 18 is not illustrated. When transistor 18 is a GaN HEMT, semiconductor substrate 21 is, for example, a silicon carbide (SiC) substrate, a sapphire substrate, or a gallium nitride (GaN) substrate. When transistor 18 is an LDMOS, semiconductor substrate 21 is, for example, a silicon (Si) substrate. Electrodes 22, 23, and 24 are metal layers such as gold layers.

Capacitive component 25 includes a dielectric substrate 26, an electrode 27 disposed on an upper surface of dielectric substrate 26, and an electrode 28 disposed on a lower surface of dielectric substrate 26. Capacitor C21 illustrated in FIG. 2 is formed by dielectric substrate 26 and electrodes 27 and 28 sandwiching dielectric substrate 26. Capacitive component 40 includes a dielectric substrate 41, an electrode 42 disposed on an upper surface of dielectric substrate 41, and an electrode 43 disposed on a lower surface of dielectric substrate 41. Capacitor C1 illustrated in FIG. 2 is formed by dielectric substrate 41 and electrodes 42 and 43 sandwiching dielectric substrate 41. Dielectric substrate 26 is, for example, alumina, and dielectric substrate 41 is, for example, a high dielectric material having a higher relative dielectric constant than alumina, such as barium titanate. Electrodes 27, 28, 42, and 43 are metal layers such as gold layers.

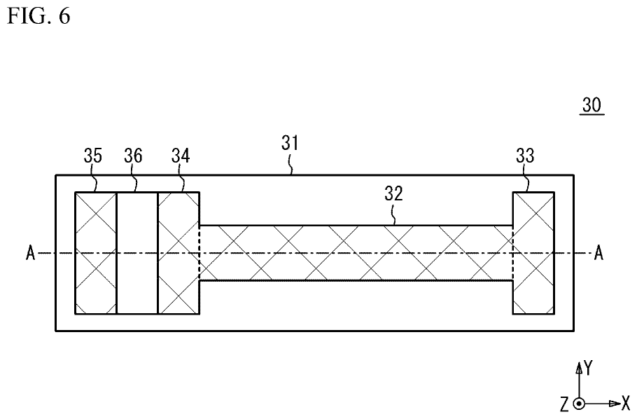

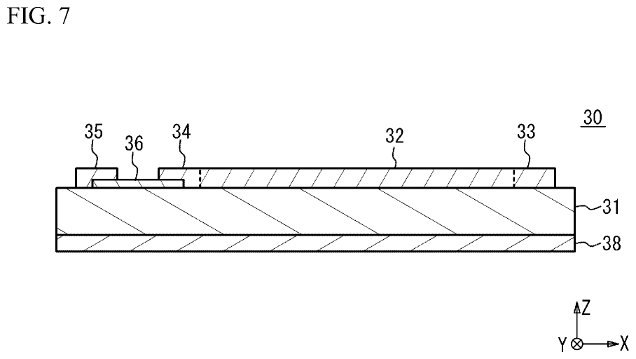

FIG. 6 is a plan view of a resistor component in the first embodiment. FIG. 7 is an A-A cross-sectional view of FIG. 6. As illustrated in FIGS. 6 and 7, resistor component 30 includes an insulated substrate 31, and a line pattern 32, a pad 33, electrodes 34 and 35, and a resistance film 36 disposed on an upper surface of insulated substrate 31. A bonding wire 64 is connected to pad 33. Line pattern 32 is a line pattern extending in the X direction. A planar shape of line pattern 32 may be a spiral shape or a meandering shape. Electrodes 34 and 35 are disposed on both end portions of resistance film 36 in the X direction so as to be electrically connected to resistance film 36. Resistor R1 illustrated in FIG. 2 is formed by resistance film 36. A part of inductor L1 illustrated in FIG. 2 is formed by line pattern 32. Resistance film 36 is, for example, a metal nitride film such as tantalum nitride (TaN or Ta₂N) or a metal oxide film, or an alloy film such as a nichrome (NiCr) alloy. An electrode 38 is disposed on a lower surface of insulated substrate 31. Line pattern 32, pad 33, and electrodes 34, 35, and 38 are formed of, for example, the same metal layer, and are, for example, a gold layer.

Electrodes 24, 38, 28 and 43 of semiconductor chip 20, resistor component 30 and capacitive components 25 and 40, respectively, are bonded to the upper surface of base substrate 12 with bonding layers 48 such as metal paste or brazing materials. Thus, the potentials of electrodes 24, 28, 38 and 43 become the reference potential supplied to base substrate 12.

A bonding wire 61 electrically connects input lead 51 and electrode 27. A bonding wire 62 electrically connects electrodes 27 and 22. A bonding wire 63 electrically connects electrode 23 and output lead 50. Bonding wire 64 electrically connects output lead 50 and pad 33. A bonding wire 65 electrically connects electrodes 35 and 42. Bonding wires 61 to 65 extend substantially in the X direction in a plan view. Bonding wires 61, 62 and 63 form inductors L21, L22 and L11, respectively, of FIG. 2. Bonding wire 64 forms a part of inductor L1 of FIG. 2.

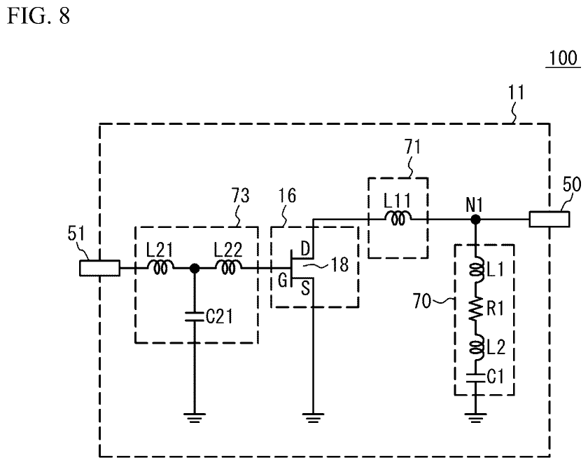

FIG. 8 is another circuit diagram of a semiconductor device in the first embodiment. As illustrated in FIG. 8, an inductor L2 is disposed between resistor R1 and capacitor C1. A first end of inductor L2 is electrically connected to the second end of resistor R1, and a second end of inductor L2 is electrically connected to the first end of capacitor C1. Bonding wire 65 illustrated in FIGS. 3 and 5 forms inductor L2 of FIG. 8. Inductor L2 do not have to be disposed. When bonding wire 65 is disposed to electrically connect resistor component 30 and capacitive component 40, inductor L2 is formed. Inductor L2 has a smaller inductance than inductor L1, for example, ½ or less of the inductance of inductor L1.

Problems in the case where a silicon substrate or an alumina substrate is used as insulated substrate 31 of resistor component 30 will be described. The silicon substrate and the alumina substrate are inexpensive and thus are insulated substrates that are easy to use. In baseband termination circuit 70, inductor L1 hardly allows the high frequency signal in the operating band to pass through resistor R1. Thus, it has been considered that a signal of large power is not applied to resistor R1. However, for example, in amplifying circuit 10 for a base station, the saturation power for the output signal of the operating band output from amplifier 16 is 10 W or more, and the amplitude of the output signal is 50 V or more. When the output signal is not sufficiently suppressed by inductor L1, a part of the output signal is applied to resistor R1, and the temperature of resistor R1 rises. This changes the resistance of resistor R1 from a desired value. Further, resistor R1 is deteriorated by temperature.

Further, for example, when the bias voltage of drain D of transistor 18 is 50 V, the amplitude of the output signal can be about 100 V. The voltage of the output signal that has not been suppressed by inductor L1 is applied to resistor R1. In addition, during operation or testing, the voltage applied to resistor R1 may happen be about 200 V. When such a high voltage is applied to resistor R1, resistor R1 deteriorates. Further, when the parasitic capacitance added to resistor R1 is large, baseband termination circuit 70 may not have desired characteristics.

Table 1 shows the thermal conductivity, bandgap energy, and relative dielectric constant of each material. In Table 1, Si, Al₂O₃, AlN, GaN and SiC represent silicon, alumina (aluminum oxide), aluminum nitride, gallium nitride and silicon carbide, respectively. The bandgap indicates bandgap energy. It is considered that a material having a large bandgap energy has a high breakdown voltage.

TABLE 1

| MATERIAL | Si | Al₂O₃ | AlN | GaN | SiC |
|---|---|---|---|---|---|
| THERMAL CONDUCTIVITY | 151 | 17 | 170 | 130 | 490 |
| [W/m · K] | | | | | |
| BANDGAP [eV] | 1.1 | 8.8 | 6.2 | 3.4 | 3.2 |
| RELATIVE DIELECTRIC | 11.9 | 10 | 8.5 | 9.5 | 6.5 |
| CONSTANT | | | | | |

When a silicon substrate is used as insulated substrate 31, the thermal conductivity of silicon is high. Thus, the temperature rise of resistor component 30 can be suppressed. However, silicon has a low bandgap energy and a low breakdown voltage. Thus, when a high voltage is applied to resistor R1, resistor component 30 deteriorates. In addition, silicon has a high relative dielectric constant. This results in parasitic capacitance, causing the characteristics of baseband termination circuit 70 to deviate from the desired characteristics.

When an alumina substrate is used as insulated substrate 31, alumina has a higher bandgap energy and a higher breakdown voltage than silicon. Thus, even when a high voltage is applied to resistor R1, the deterioration of resistor component 30 can be suppressed. In addition, alumina has a lower relative dielectric constant than silicon, and thus can suppress the characteristics of baseband termination circuit 70 from deviating from desired characteristics. However, alumina has low thermal conductivity. Thus, the temperature of resistor component 30 rises, and the resistance changes.

When baseband termination circuit 70 is disposed in amplifying circuit 10, a substrate having a thermal conductivity of 20 W/m·K or more and a bandgap energy of 1.5 eV or more is used as insulated substrate 31 of resistor component 30 forming resistor R1. By setting the thermal conductivity of insulated substrate 31 to be 20 W/m·K or more, the thermal conductivity of insulated substrate 31 is higher than alumina. Thus, the temperature rise of resistor component 30 can be suppressed. From the viewpoint of suppressing the temperature rise, the thermal conductivity of insulated substrate 31 is, for example, 50 W/m·K or more, or 100 W/m·K or more. The thermal conductivity of insulated substrate 31 is 1000 W/m·K or less in a general material. By setting the bandgap energy of insulated substrate 31 to 1.5 eV or more, the bandgap energy is higher than the bandgap energy of silicon. Thus, even when a high voltage is applied to resistor R1, deterioration of resistor component 30 can be suppressed. From the viewpoint of improving the breakdown voltage, the bandgap energy of insulated substrate 31 is, for example, 2.0 eV or more, or 3.0 eV or more. The bandgap energy of insulated substrate 31 is 10 eV or less in a general material.

When an aluminum nitride substrate, a gallium nitride substrate, or a silicon carbide substrate is used as insulated substrate 31, the thermal conductivity of insulated substrate 31 can be made higher than that of alumina, and the breakdown voltage can be made higher than that of silicon. Since aluminum nitride has a higher bandgap energy than gallium nitride and silicon carbide, an aluminum nitride substrate can be used as insulated substrate 31 for improving the breakdown voltage. The relative dielectric constants of aluminum nitride, gallium nitride and silicon carbide are lower than the relative dielectric constants of silicon and alumina. Thus, it is possible to suppress the characteristics of baseband termination circuit 70 from deviating from desired characteristics due to parasitic capacitance. The relative dielectric constant of insulated substrate 31 can be set to, for example, 10 or less. The aluminum nitride substrate, the gallium nitride substrate, or the silicon carbide substrate used as insulated substrate 31 is, for example, a polycrystal or a single crystal. By using a polycrystalline substrate or a sintered substrate as insulated substrate 31, inexpensive insulated substrate 31 can be used. A thickness of insulated substrate 31 is, for example, 300 μm or less, 200 μm or less, or 100 μm or less. This can suppress the temperature rise of resistor component 30. From the viewpoint of manufacturing, a thickness of resistor component 30 is, for example, 10 μm or more.

In baseband termination circuit 70, an absolute value of an impedance of inductor L1 at a center frequency of an operating band of amplifier 16 is larger than an absolute value of an impedance of capacitor C1 at a frequency corresponding to a bandwidth of the operating band. Thus, inductor L1 suppresses leakage of a high frequency signal of the operating band to the reference potential, and capacitor C1 allows a low frequency signal to pass through to the reference potential. This allows inductor L1 and capacitor C1 to function as baseband termination circuit 70. The absolute value of the impedance of inductor L1 may be 10 times or more, or 20 times or more of the absolute value of the impedance of capacitor C1 at the frequency corresponding to the bandwidth of the operating band.

The absolute value of the impedance of inductor L1 is, for example, 10Ω or more, or 100Ω or more. The absolute value of the impedance of capacitor C1 is, for example, 1Ω or less, or 0.1Ω or less. This allows inductor L1 and capacitor C1 to function as baseband termination circuit 70.

Inductor L1 has an inductance of, for example, 100 pH or more, or 1 nH or more. Capacitor C1 has a capacitance of, for example, 100 pF or more, or 1 nF or more. When inductor L1 and capacitor C1 are too large, the semiconductor device becomes large. In this regard, inductor L1 has an inductance of 1 μH or less, and capacitor C1 has a capacitance of 1 μF or less. This allows inductor L1 and capacitor C1 to function as baseband termination circuit 70.

When amplifying circuit 10 is used in a base station of mobile communication, the center frequency of the operating band of amplifier 16 is, for example, 0.5 GHz to 10 GHZ, and the bandwidth of the operating band is, for example, 0.01 times to 0.5 times the center frequency of the operating band. For example, the bandwidth of the operating band is 100 MHz or more. The center frequency of the operating band of amplifier 16 may be 0.5 GHz to 5 GHZ, and is 0.1 times to 0.3 times the center frequency of the operating band.

A saturation power for the high frequency signal output from output terminal Tout (for example, a saturation power of amplifier 16) is, for example, 10 W or more, 100 W or more, or 500 W or more. In such a case, a signal of large power may be applied to resistor component 30. Thus, an aluminum nitride substrate, a gallium nitride substrate, or a silicon carbide substrate is used as insulated substrate 31. Thus, even when a large power is applied to resistor component 30, a change or deterioration in the characteristics of resistor component 30 can be suppressed. The saturation power output from output terminal Tout is, for example, 1500 W or less.

Resistor component 30 mounted on or over base substrate 12 need only form resistor R1, and capacitor C1 and amplifier 16 do not have to be disposed in capacitive component 25 or semiconductor chip 20, respectively. Capacitor C1 and amplifier 16 are disposed in capacitive component 25 and semiconductor chip 20 respectively, both mounted on base substrate 12. This allows semiconductor device 100 to be miniaturized.

### [First Modification of First Embodiment]

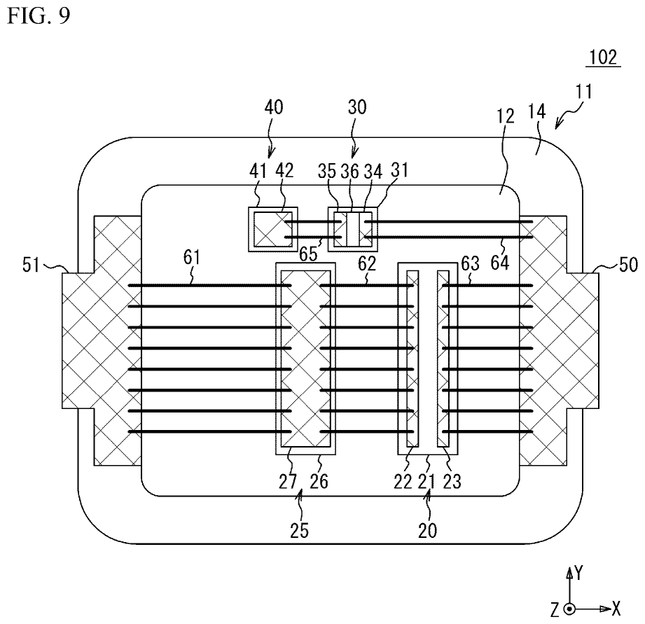

FIG. 9 is a plan view of a semiconductor device according to a first modification of the first embodiment. As illustrated in FIG. 9, in a semiconductor device 102 of first modification of the first embodiment, resistor component 30 is not provided with line pattern 32 or pad 33. Bonding wire 64 electrically connects output lead 50 and electrode 34. Bonding wire 64 forms inductor L1 of FIG. 2. Other configurations are the same as those of the first embodiment, and the description thereof is omitted.

### [Second Modification of First Embodiment]

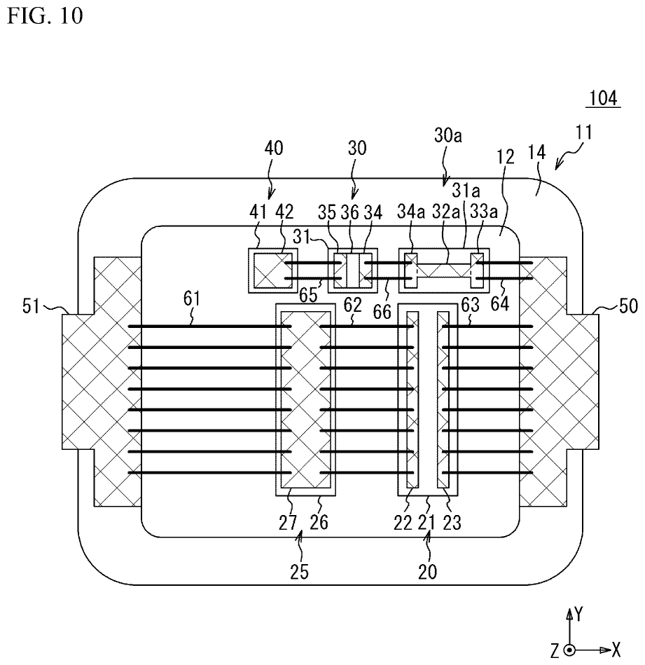

FIG. 10 is a plan view of a semiconductor device according to second modification of the first embodiment. As illustrated in FIG. 10, in a semiconductor device 104 of second modification of the first embodiment, a wiring component 30a is disposed separately from resistor component 30. Wiring component 30a includes an insulated substrate 31a, an electrode (not illustrated) disposed on a lower surface of insulated substrate 31a, and a line pattern 32a, pads 33a and 34a disposed on an upper surface of insulated substrate 31a. The electrode on the lower surface of insulated substrate 31a is bonded to base substrate 12 with a conductive bonding layer, and a reference potential is supplied. Bonding wire 64, line pattern 32a and a bonding wire 66 form inductor L1 of FIG. 2. Insulated substrates 31 and 31a may be substrates made of the same material or substrates made of different materials. From the viewpoint of suppressing the characteristics of baseband termination circuit 70 from deviating from desired characteristics due to a temperature rise in wiring component 30a, deterioration caused by a high voltage, and parasitic capacitance, insulated substrate 31a may be an aluminum nitride substrate, a gallium nitride substrate, or a silicon carbide substrate. Other configurations are the same as those of the first embodiment, and the description thereof is omitted.

As in the first embodiment and its modifications 1 and 2, inductor L1 may be formed by bonding wire 64, or may be formed by bonding wire 64 and line pattern 32 or 32a. As described in patent literature 1, at least a part of inductor L1 may be a line pattern disposed on frame body 14.

In order to suppress the temperature rise of inductor L1 due to the current flowing through inductor L1, for example, a substrate having a thermal conductivity of 20 W/m·K or more and a bandgap energy of 1.5 eV or more, such as an aluminum nitride substrate, a gallium nitride substrate, or a silicon carbide substrate is used as insulated substrate 31 or 31a provided with line pattern 32 or 32a, respectively. For miniaturization, line pattern 32 may be disposed in resistor component 30.

As in second modification of the first embodiment, when line pattern 32a forming a part of inductor L1 is disposed in wiring component 30a separated from resistor component 30, the material of insulated substrate 31a may be the same as or different from that of insulated substrate 31. Line pattern 32a does not generate heat as much as resistance film 36. Thus, the thermal conductivity of insulated substrate 31a may be lower than the thermal conductivity of insulated substrate 31.

### Second Embodiment

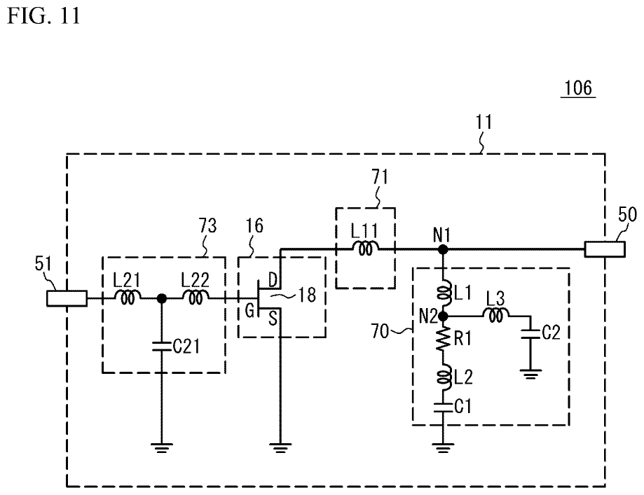

FIG. 11 is a circuit diagram of a semiconductor device according to a second embodiment. As illustrated in FIG. 11, an inductor L3 and a capacitor C2 are disposed in a semiconductor device 106 of the second embodiment compared to FIG. 8 of the first embodiment. A first end of inductor L3 is electrically connected to a node N2 between inductor L1 and resistor R1. A first end of capacitor C2 is electrically connected to a second end of inductor L3, and a second end of capacitor C2 is electrically connected to a reference potential. The capacitance of capacitor C2 is different from the capacitance of capacitor C1. For example, capacitor C2 has a capacitance of ½ or less of the capacitance of capacitor C1. This makes it possible to increase the band of the frequency suppressed by baseband termination circuit 70.

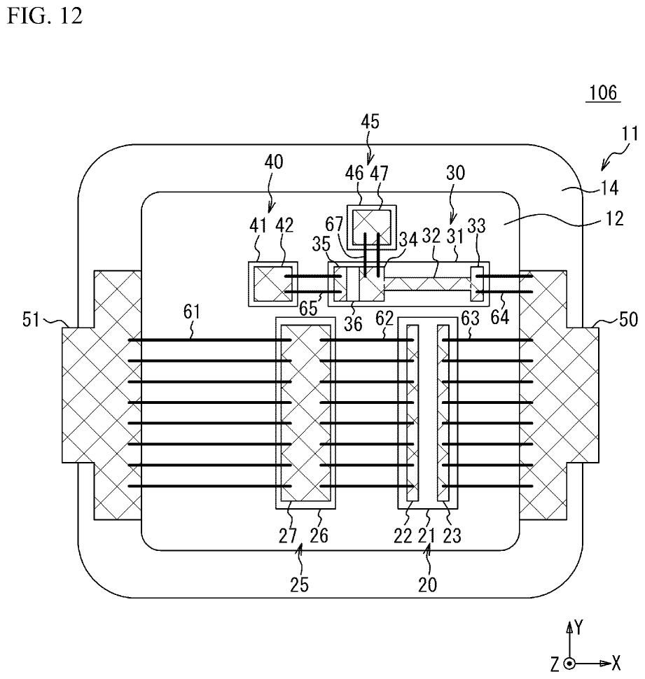

FIG. 12 is a plan view of a semiconductor device according to the second embodiment. As illustrated in FIG. 12, in semiconductor device 106 of the second embodiment, a capacitive component 45 is disposed on base substrate 12. Capacitive component 45 includes a dielectric substrate 46, an electrode 47 disposed on an upper surface of dielectric substrate 46, and an electrode (not illustrated) disposed on a lower surface of dielectric substrate 46. The electrode on the lower surface of dielectric substrate 46 is bonded to base substrate 12 with a conductive bonding layer, and a reference potential is supplied. A bonding wire 67 electrically connects electrodes 34 and 47. Capacitor C2 illustrated in FIG. 11 is formed by dielectric substrate 46, electrode 47 and the electrode on the lower surface of dielectric substrate 46 sandwiching dielectric substrate 46. Inductor L3 illustrated in FIG. 11 is formed by bonding wire 67. Dielectric substrates 46 and 41 may be substrates made of the same material or substrates made of different materials. Inductor L3 do not have to be disposed. Inductor L3 is formed by disposing bonding wire 67 that electrically connects resistor component 30 and capacitive component 45. Inductor L3 has a smaller inductance than inductor L1, for example, ½ or less of the inductance of inductor L1.

Electrode 47 of capacitive component 45 may be disposed in resistor component 30. In this case, resistor R1 and capacitor C2 are integrated on the same insulated substrate 31. In this case, inductor L3 of FIG. 11 is a line pattern or a via wire connecting electrodes 34 and 47. Inductor L3 has a smaller inductance than bonding wire 67.

### [First Modification of Second Embodiment]

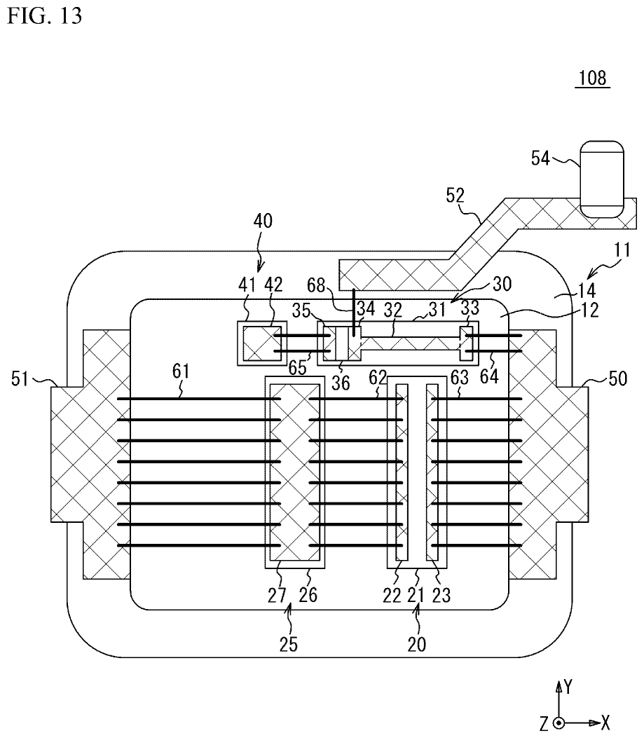

FIG. 13 is a plan view of a semiconductor device in first modification of the second embodiment. As illustrated in FIG. 13, in a semiconductor device 108 of first modification of the second embodiment, a lead 52 is disposed on frame body 14. A bonding wire 68 electrically connects electrode 34 and lead 52. An end portion of lead 52 extends outside package 11 and is electrically connected to a first end of an external capacitive component 54. A second end of capacitive component 54 is electrically connected to a reference potential. Bonding wire 68 and lead 52 form inductor L3 of FIG. 11, and capacitive component 54 corresponds to capacitor C2. By externally attaching capacitive component 54, the capacitance of capacitor C2 can be increased. Capacitor C2 has, for example, a larger capacitance than capacitor C1, for example, twice or more the capacitance of capacitor C1. This makes it possible to increase the band of the frequency suppressed by baseband termination circuit 70. Other configurations are the same as those of the second embodiment, and the description thereof is omitted.

In the second embodiment and its modification, a first end of bonding wire 67 or 68 may be connected to electrode 35 instead of electrode 34, or may be connected to pad 33. Although the example in which one capacitor C2 is disposed has been described, two or more capacitors C2 connected in parallel to capacitor C1 may be disposed between node N1 and the reference potential. Capacitor C2 may be disposed in the modifications 1 and 2 of the first embodiment.

As in the second embodiment and its modification, capacitor C2 (third capacitor) is connected in parallel with capacitor C1 between the line, which is located between amplifier 16 and output terminal Tout, and the reference potential. Thus, the capacitance of capacitor C1 is made different from that of capacitor C2, and thereby the band of the frequency suppressed by baseband termination circuit 70 can be increased. Further, resonance is likely to occur due to capacitors C1 and C2. Thus, the resonance can be suppressed by disposing resistor R1.

### Third Embodiment

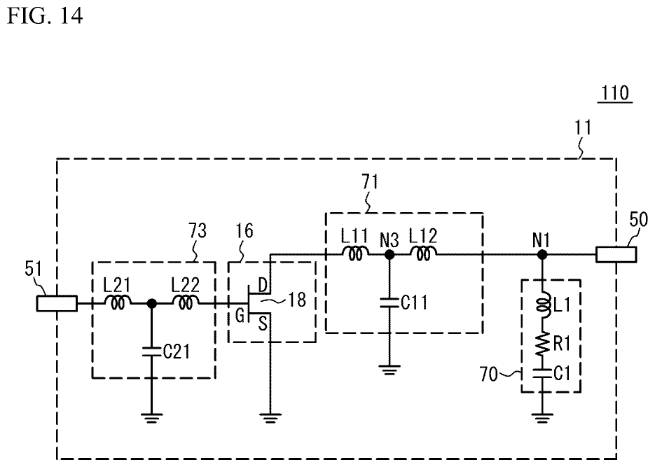

FIG. 14 is a circuit diagram of a semiconductor device according to a third embodiment. As illustrated in FIG. 14, in a semiconductor device 110 of the third embodiment, internal output matching circuit 71 is an L-C-L T-type low-pass circuit, and includes inductors L11 and L12 and a capacitor C11. Inductors L11 and L12 are connected in series between amplifier 16 and node N1. Capacitor C11 is shunt-connected to a node N3, which is located between inductors L11 and L12.

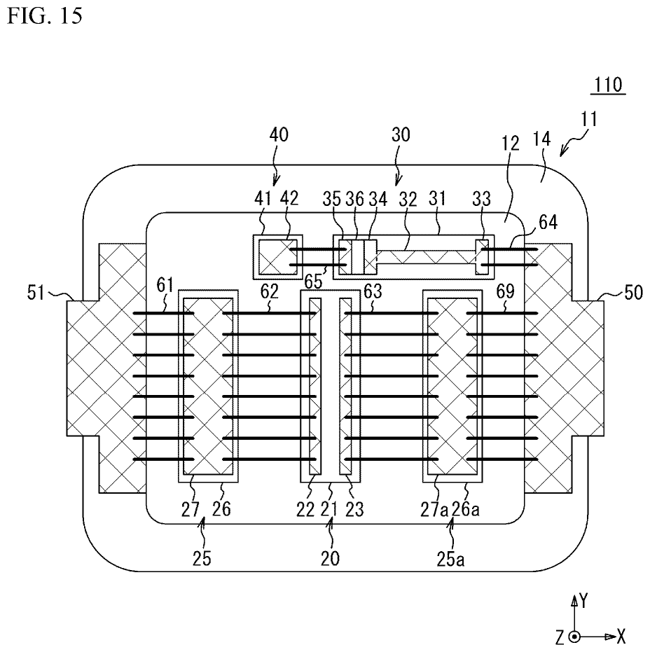

FIG. 15 is a plan view of a semiconductor device according to the third embodiment. As illustrated in FIG. 15, in semiconductor device 110 of the third embodiment, a capacitive component 25a is mounted in one package 11 in addition to semiconductor chip 20, capacitive components 25 and 40, and resistor component 30. Capacitive component 25a includes a dielectric substrate 26a, an electrode 27a disposed on an upper surface of dielectric substrate 26a, and an electrode (not illustrated) disposed on a lower surface of dielectric substrate 26a. Capacitor C11 illustrated in FIG. 14 is formed by dielectric substrate 26a, electrode 27a and the electrode (not illustrated) sandwiching dielectric substrate 26a. Dielectric substrate 26a and electrode 27a of capacitive component 25a have the same structure as those of capacitive component 25.

Bonding wire 63 electrically connects electrodes 23 and 27a. A bonding wire 69 electrically connects electrode 27a and output lead 50. Bonding wires 63 and 69 form inductors L11 and L12, respectively, of FIG. 14.

Internal output matching circuit 71 may include inductors L11 and L12 (second inductor) and capacitor C11 (second capacitor). Capacitor C11 used in a matching circuit has a capacitance of 10 pF or less, which is small. Thus, capacitor C1 has a larger capacitance than capacitor C11, for example, 10 times or more, or 100 times or more. Inductors L11 and L12 used in the matching circuit has an inductance of 10 nH or less, which is small. Thus, inductor L1 has a larger inductance than inductors L11 and L12, for example, 10 times or more, or 100 times or more. This allows inductor L1 and capacitor C1 to function as baseband termination circuit 70. Other configurations are the same as those of the first embodiment, and the description thereof will be omitted.

### Fourth Embodiment

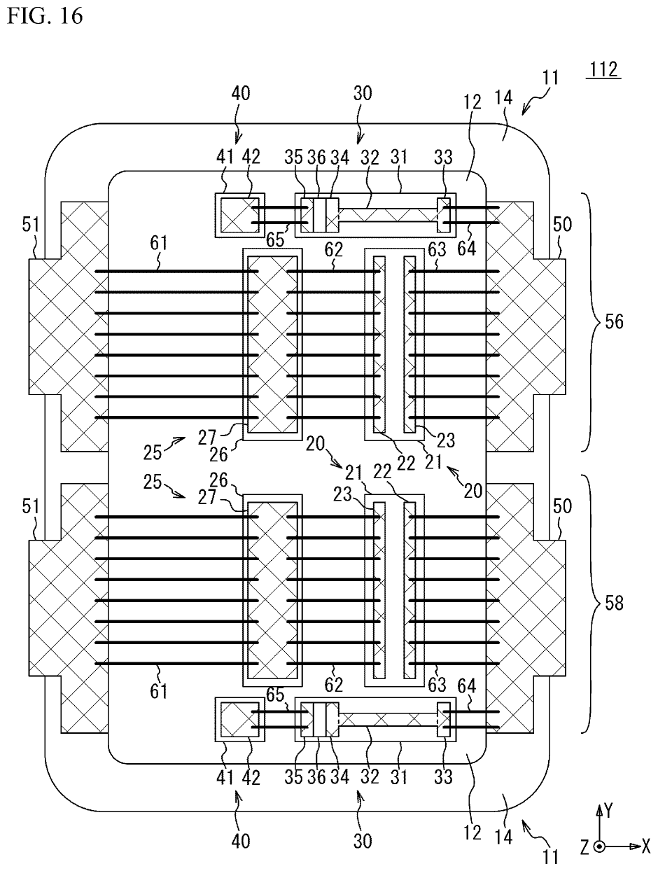

A fourth embodiment is an example in which a plurality of semiconductor chips are disposed in a package. FIG. 16 is a plan view of a semiconductor device according to the fourth embodiment. As illustrated in FIG. 16, in a semiconductor device 112 of the fourth embodiment, two sets 56 and 58 each including semiconductor chip 20, capacitive components 25 and 40, resistor component 30, input lead 51 and output lead 50, are disposed in one package 11. Two sets 56 and 58 are arranged in the Y direction. Set 56 is, for example, a main amplifier of a Doherty amplifying circuit. Set 58 is, for example, a peak amplifier of a Doherty amplifying circuit. Three or more sets 56 and 58 may be disposed. The other configurations are the same as those of the first embodiment, and the description thereof is omitted. In the modifications of the first embodiment, the second embodiment, and the modification thereof, a plurality of sets 56 and 58 may be disposed.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

What is claimed is:

1. An amplifying circuit comprising:
an amplifier that amplifies a high frequency signal input to an input terminal and outputs the amplified high frequency signal to an output terminal;
a first inductor having a first end connected to a line between the amplifier and the output terminal;
a resistor component having a first end connected to a second end of the first inductor, the resistor component including an insulated substrate mounted on or over an upper surface of a base substrate and having a thermal conductivity of 20 W/m·K or more and a bandgap energy of 1.5 eV or more, and a resistance film disposed on an upper surface of the insulated substrate; and
a first capacitor having a first end connected to a second end of the resistor component and a second end connected to a reference potential, wherein
an absolute value of an impedance of the first inductor at a center frequency of an operating band of the amplifier is larger than an absolute value of an impedance of the first capacitor at a frequency corresponding to a bandwidth of the operating band.

2. The amplifying circuit according to claim 1, wherein
the absolute value of the impedance of the first inductor at the center frequency of the operating band is 10Ω or more, and
the absolute value of the impedance of the first capacitor at the frequency corresponding to the bandwidth of the operating band is 1Ω or less.

3. The amplifying circuit according to claim 1, wherein
the first inductor has an inductance of 100 pH or more, and
the first capacitor has a capacitance of 100 pF or more.

4. The amplifying circuit according to claim 1, further comprising
a matching circuit disposed in the line and including a second inductor and a second capacitor, wherein
the first inductor has a larger inductance than the second inductor, and
the first capacitor has a larger capacitance than the second capacitor.

5. The amplifying circuit according to claim 1, wherein
the center frequency of the operating band is 0.5 GHz to 10 GHz, and
the bandwidth of the operating band is 100 MHz or more.

6. The amplifying circuit according to claim 5, wherein
a saturation power for the high frequency signal to be output from the output terminal is 10 W or more.

7. The amplifying circuit according to claim 1, wherein
the first inductor includes a line pattern disposed on the upper surface of the insulated substrate.

8. The amplifying circuit according to claim 1, further comprising
a third capacitor connected in parallel with the first capacitor between the line and the reference potential.

9. The amplifying circuit according to claim 1, wherein
the insulated substrate is an aluminum nitride substrate, a gallium nitride substrate, or a silicon carbide substrate.

10. The amplifying circuit according to claim 1, wherein
the first capacitor includes a dielectric substrate mounted on or over the upper surface of the base substrate, and an electrode disposed on an upper surface of the dielectric substrate and connected to the second end of the resistor component, and
the amplifier includes a semiconductor substrate mounted on or over the upper surface of the base substrate, and a transistor disposed on the semiconductor substrate.
